(19) United States
(12) Patent Application Publication
(10) Pub. No.: US 2008/0290436 A1
(43) Pub. Date: Nov. 27, 2008

(54) Photon guiding structure and method of forming the same

(76) Inventor: Giovanni De Amicis, L'Aquila (AQ) (IT)

Correspondence Address: DICKSTEIN SHAPIRO LLP, 1825 EYE STREET NW, Washington, DC, 20006-5403, US

(21) Appl. No.: 11/907,271

(22) Filed: Oct. 10, 2007

(30) Foreign Application Priority Data
May 22, 2007 (IT) RM2007A000280

(51) Int. Cl. H01L 31/0232; H01L 31/18

(52) U.S. Cl. 257/432; 438/70; 257/E31.127

(57) ABSTRACT

A photon guiding structure for reducing optical crosstalk in an image sensor and method of forming the same. The method includes forming a trench within an interlayer dielectric region formed over a photo-conversion device. The trench is formed such that it is vertically aligned with and has a horizontal cross-sectional shape similar to that of the photo-conversion device. A material is formed within the trench and a dielectric is formed over the material. The lined trench causes photons to strike the proper photo-conversion device and, as such, reduces the chance that photons will impinge upon neighboring photo-conversion devices.

### FIELD OF THE INVENTION

Embodiments of the invention relate generally to the field of semiconductor devices and more particularly to a photon guiding structure and method of forming the same.

### BACKGROUND OF THE INVENTION

The semiconductor industry uses different types of semiconductor-based image sensors, including charge coupled devices (CCDs), photodiode arrays, charge injection devices (CIDs), hybrid focal plane arrays, and complementary metal oxide semiconductor (CMOS) image sensors. Current applications of such image sensors include cameras, scanners, machine vision systems, vehicle navigation systems, video telephones, computer input devices, surveillance systems, auto focus systems, star trackers, motion detector systems, image stabilization systems, and other image acquisition and processing systems.

Semiconductor image sensors include an array of pixel cells. Each pixel cell contains a photo-conversion device for converting incident light to an electrical signal. The electrical signals produced by the array of photo-conversion devices are processed to render a digital image.

The amount of charge generated by the photo-conversion device corresponds to the intensity of light impinging on the photo-conversion device. Accordingly, it is important that all of the light directed to a photo-conversion device impinges on the photo-conversion device rather than being reflected or refracted toward another photo-conversion device, which would produce optical crosstalk.

For example, optical crosstalk may exist between neighboring photo-conversion devices in a pixel array. Ideally, all incident photons on a pixel cell are directed towards the photo-conversion device corresponding to that pixel cell. In reality, some of the photons are refracted and reach adjacent photo-conversion devices producing optical crosstalk.

Optical crosstalk can bring about undesirable results in the images produced by imaging devices. The undesirable results can become more pronounced as the density of pixel cells in image sensors increases and as pixel cell size correspondingly decreases. Optical crosstalk can cause a blurring or reduction in contrast in images produced by the imaging device. Optical crosstalk can also degrade the spatial resolution, reduce overall sensitivity, cause color mixing, and lead to image noise after color correction. Accordingly, there is a need and desire for an improved method and structure for reducing optical crosstalk in imaging devices and increasing overall sensitivity without adding complexity to the manufacturing process and/or significantly increasing fabrication costs.

### BRIEF DESCRIPTION OF THE DRAWINGS

FIG. 1 is a schematic cross-sectional view of a pixel cell formed in accordance with an embodiment described herein.

FIGS. 2-4 and 6-8 are schematic cross-sectional views of the pixel cell in FIG. 1 in intermediate stages of fabrication.

FIG. 5 is a top plan view of a portion of a pixel cell having a photon guiding structure with a circular external end.

FIG. 9 is a block diagram of an image sensor according to an embodiment described herein.

FIG. 10 is a block diagram of a processing system including the image sensor of FIG. 9.

### DETAILED DESCRIPTION OF THE INVENTION

In the following detailed description, reference is made to certain embodiments of the invention. These embodiments are described with sufficient detail to enable those skilled in the art to practice them. It is to be understood that other embodiments may be employed, and that various structural, logical and electrical changes may be made.

The term “substrate” used in the following description may include any supporting structure including, but not limited to, a semiconductor substrate that has an exposed substrate surface. A semiconductor substrate should be understood to include silicon, silicon-on-insulator (SOI), silicon-on-sapphire (SOS), doped and undoped semiconductors, epitaxial layers of silicon supported by a base semiconductor foundation, and other semiconductor structures, including those made of semiconductors other than silicon. When reference is made to a semiconductor substrate in the following description, previous process steps may have been utilized to form regions or junctions in or over the base semiconductor or foundation. The substrate also need not be semiconductor-based, but may be any support structure suitable for supporting an integrated circuit, including, but not limited to, metals, alloys, glasses, polymers, ceramics, and any other supportive materials as is known in the art.

The term “pixel” or “pixel cell” refers to a picture element unit cell containing a photo-conversion device for converting electromagnetic radiation to an electrical signal. Typically, the fabrication of all pixel cells in an image sensor will proceed simultaneously in a similar fashion.

Although embodiments are described herein with reference to the architecture and fabrication of one or a limited number of pixel cells, it should be understood that this description is representative for a plurality of pixel cells as typically would be arranged in an imager array having pixel cells arranged, for example, in rows and columns.

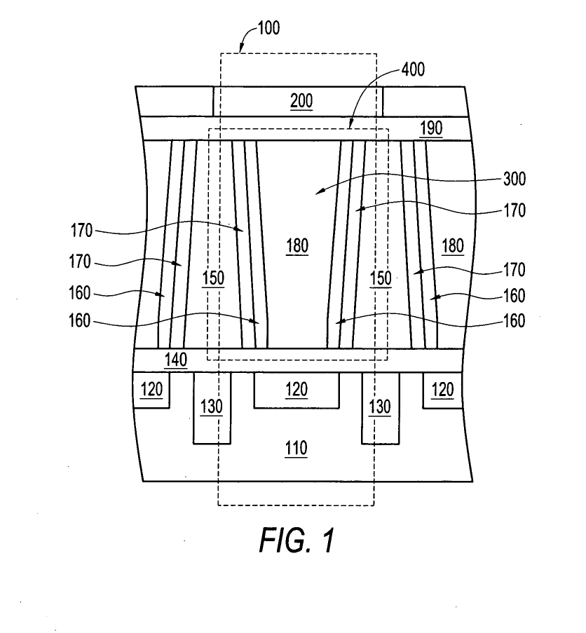

Referring to FIGS. 1-8, one embodiment is now described with reference to the formation of a portion of a pixel cell 100. Throughout the drawings, like reference numbers are used consistently for like features. For illustrative purposes, the embodiment is described with reference to a pixel cell 100 for a CMOS image sensor. It should be readily understood that embodiments could apply to CCD and other image sensors. In addition, the embodiment is described as forming a single pixel cell 100, but as mentioned earlier, fabrication of all pixel cells in an image sensor can proceed simultaneously.

Each pixel cell 100 includes a photo-conversion device 120 formed in a semiconductor substrate 110, a protective layer 140 formed over the active area of the pixel cell 100, and a photon guiding structure 400 for guiding photons down to the photo-conversion device 120. Isolation trenches 130 are used to separate the pixel cells 100 from each other. Each photon guiding structure 400 comprises a trench 300 that is lined with a material 170 designed to internally reflect photons down to its associated photo-conversion device 120. Each trench 300 is also lined with a dielectric layer 160 over material 170 and the remaining portion of each trench 300 is filled with an optically transparent material 180. A passivation layer 190 is formed over the photon guiding structure 400 of each pixel cell 100. An optional color filter array 200 is formed over the passivation layer 190 if the pixel cell 100 is being used to detect a color component (i.e., red, blue, green). Otherwise, color filter array 200 is not required.

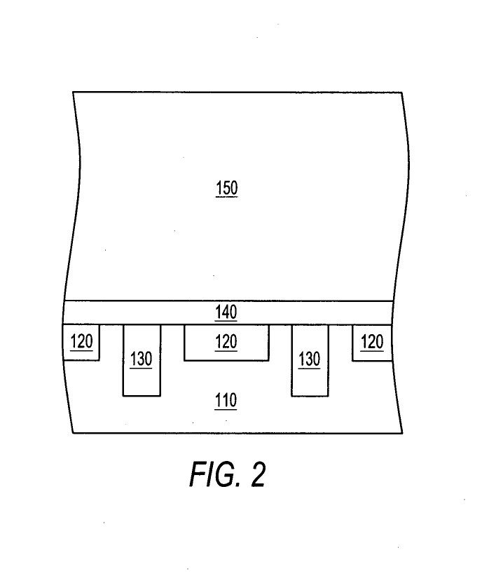

FIGS. 2-4 and 6-8 depict process steps for forming pixel cells 100 of FIG. 1. No particular order is required for any of the actions described herein, except for those logically requiring the results of prior actions. Accordingly, while the actions below are described as being performed in a general order, the order is but one embodiment of the invention and can be altered.

Referring to FIG. 2, the photo-conversion device 120 and the isolation trenches 130 are formed in the substrate 110 by any method known in the art. A protective layer 140, typically formed of silicate material such as borophosphosilicate glass (BPSG) or tetraethyl orthosilicate (TEOS), is formed over the substrate 110, photo-conversion device 120, and trenches 130. An interlayer dielectric (ILD) region 150 is then formed over the protective layer 140. The ILD region 150 may contain any number of layers and may be formed of any suitable material. For example, the ILD region 150 may include ILD layers, passivation layers, and metallization layers (not shown). The ILD region 150 may also include conductive structures such as metal lines for forming connections between devices of the pixel cell 100 and external devices (not shown); however, no such conductive structures are provided over the photo-conversion device 120. For simplicity, the layers within the ILD region 150 are depicted collectively as layer 150. Any suitable technique may be used to form the layers within the ILD region 150.

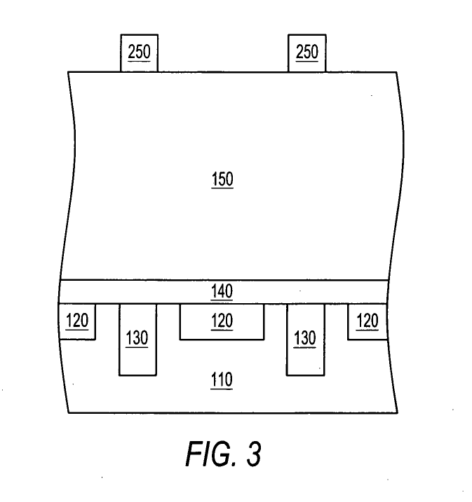

Referring to FIG. 3, a patterned resist 250 is applied to the ILD region 150 using, for example, photolithography techniques to create a resist pattern in which the location for a photon guiding structure 400 (FIG. 1) is exposed for etching. Preferably, each photo-conversion device 120 has a corresponding photon guiding structure 400 (FIG. 1). The ILD region 150 can be patterned to form a photon guiding structure 400 (FIG. 1) having any desired shape. In one embodiment, the ILD region 150 is patterned such that the photon guiding structure 400 (FIG. 1) is substantially vertically aligned with and has approximately the same shape as the photo-conversion device 120 when viewed from a top-down perspective.

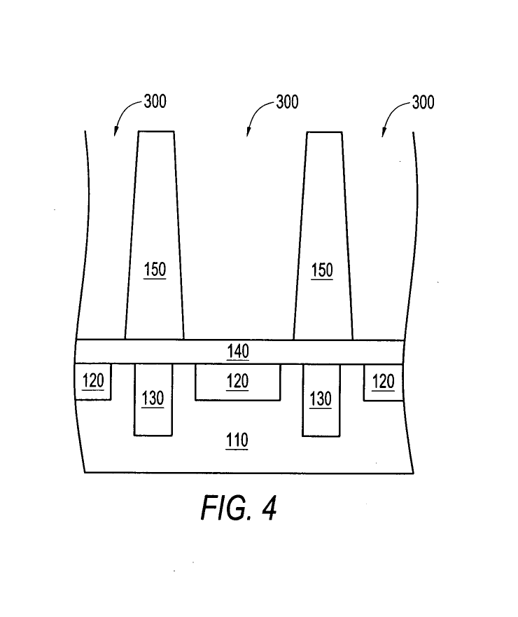

In FIG. 4, the uncovered parts of the ILD region 150 are etched away using any known etching technique to form a trench 300 above each photo-conversion device 120. Preferably, the trench 300 is dry etched. The depth, width and overall shape of the trench 300 can be tailored depending on the need, and may extend through any number of layers present above the photo-conversion device 120. In one embodiment, the trench 300 begins at a level below a later formed optional color filter array 200 (FIG. 1) and extends through the ILD region 150 down to the protective layer 140 formed over the photo-conversion device 120.

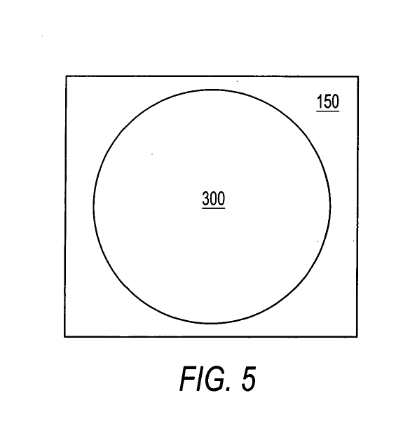

As previously mentioned, the trench 300 can be formed having any desired horizontal cross-sectional shape. FIG. 5 is a top plan view of the ILD region 150 with trenches 300 having a circular horizontal cross-sectional shape (i.e., the trenches 300 are cylindrical). The trenches may also have rectangular or pentagonal horizontal cross-sectional shapes. Once the etching process is complete, the resist 250 (FIG. 3) is removed and the surface of the structure shown in FIG. 4 is strip cleaned.

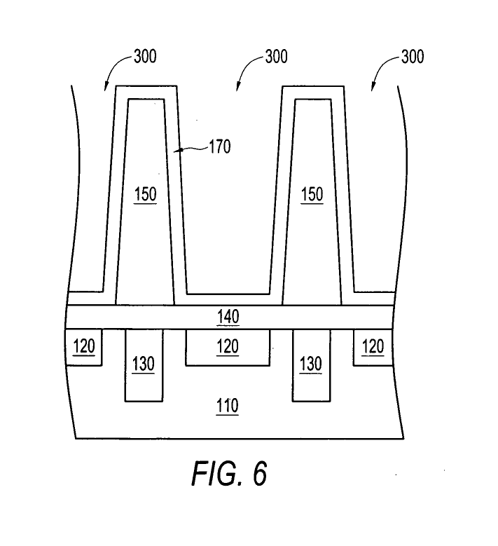

Referring to FIG. 6, each trench 300 is lined with a material 170 that internally reflects photons down the photon guiding structure 400 (FIG. 1) using any known technique in the art. For example, the material layer 170 can be formed by physical vapor deposition (PVD), direct current (DC) sputter deposition or radio frequency (RF) sputter deposition and the material layer 170 can have a thickness within the range of approximately 50 Å to approximately 1000 Å. Preferably, the thickness of the material layer 170 is about 400 Å. Suitable materials for the material layer 170 include metals and metal alloys having a high light reflectivity. For example, metals such as aluminum, copper, silver, tungsten, titanium, and gold have a high light reflectivity and can serve as optical barrier material. The metals mentioned herein do not represent an exhaustive list of possible metals and metal alloys that can be used. Alternatively, material layer 170 has an index of refraction that is less than the index of refraction of the optically transparent material 180 (FIG. 1) filling the trench 300. A non-limiting list of materials suitable for the material layer 170 include silicon nitride, titanium oxide, and titanium nitride. The kind of material suitable for the material layer 170 is in no way limited by these examples.

In one embodiment, the photon guiding structure 400 shown in FIG. 1 comprises a highly reflective material layer 170. In another embodiment, the photon guiding structure 400 comprises a material layer 170 having an index of refraction that is less than the index of refraction of the optically transparent material 180 filling the trench 300. In both embodiments, photons entering the photon guiding structure 400 (FIG. 1) are directed toward the photo-conversion device 120, thereby reducing optical crosstalk between neighboring pixel cells 100.

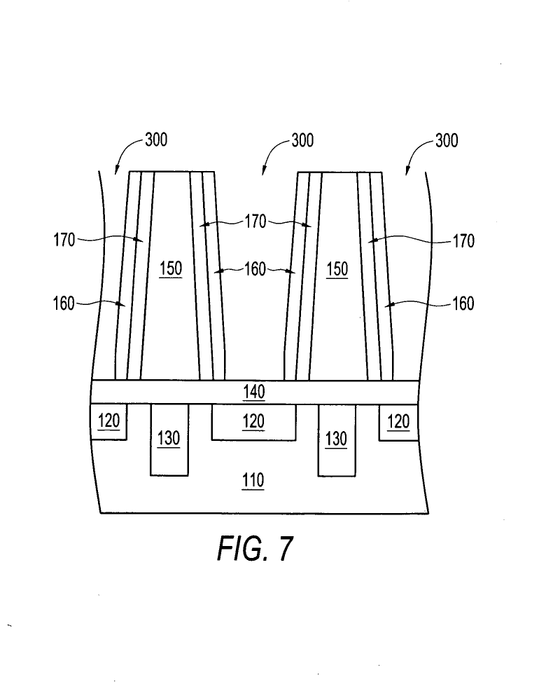

Referring to FIG. 7, a dielectric layer 160 is deposited over the material layer 170 using any known technique in the art. For example, the dielectric layer 160 can be formed by physical vapor deposition (PVD), direct current (DC) sputter deposition or radio frequency (RF) sputter deposition. Preferably, the dielectric layer 160 is formed by plasma enhanced chemical vapor deposition (PECVD) or sub-atmospheric chemical vapor deposition (SACVD). Moreover, the dielectric layer 160 can have a thickness within the range of approximately 50 Å to approximately 1000 Å. Preferably, the thickness of the dielectric layer 160 is about 400 Å. The material layer 170 and the dielectric layer 160 may have approximately the same thickness, but this is not a requirement. It is possible to adjust the thickness of each layer 160, 170 according to need. Suitable materials for the dielectric layer 160 include, among others, TEOS, un-doped silicate glass, and silicon nitride.

The material layer 170 and the dielectric layer 160 are then removed from the bottom of the trench 300 to expose the protective layer 140 and from the area adjacent the top of the trench 300 to expose the ILD region 150. Any known technique may be used to achieve the desired result shown in FIG. 7 including, but not limited to dry etching. Due to the isotropic nature of the dry etching process, the dielectric layer 160 is needed to prevent the material layer 170 from being etched away from the sidewall of the trench 300.

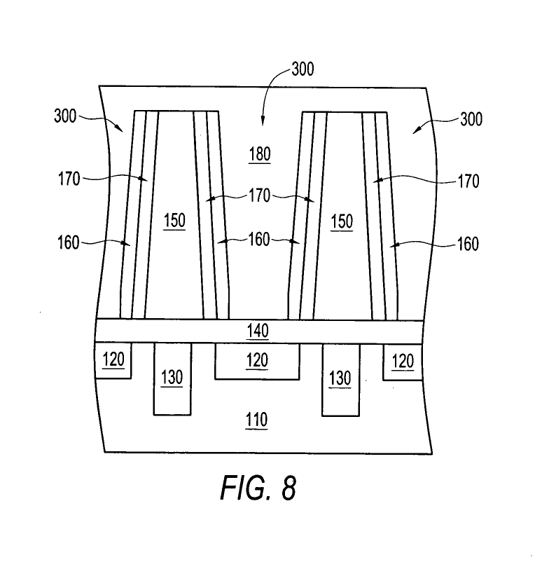

In FIG. 8, the trench 300 is filled with an optically transparent material 180 that is different from the material used to form the dielectric layer 160 using any suitable deposition method known in the art. The dielectric layer 160 isolates the material layer 170 from the optically transparent material 180 filling the trench 300. This is desirable since the material layer 170 may be physically or chemically incompatible with the optically transparent material 180. The optically transparent material 180 can be, for example, undoped silicate glass (USG), spin-on dielectric (SOD), optically-transparent flowable oxide or photoresist.

The intermediate structure of FIG. 8 is then planarized using a chemical-mechanical planarization (CMP) process to remove the optically transparent material 180 and expose the top surface of the ILD region 150. This process is followed by forming a passivation layer 190 and an optional color filter array 200 to form the structure shown in FIG. 1.

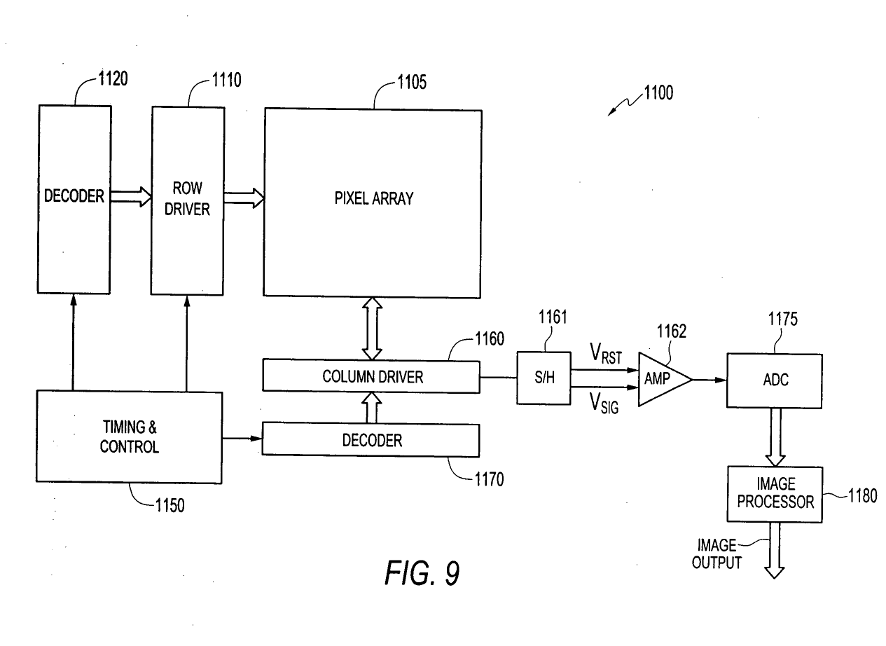

FIG. 9 illustrates a CMOS image sensor 1100 that includes an array 1105 of pixel cells constructed according to an embodiment. That is, each pixel cell 100 uses the structure illustrated in FIG. 1. The array 1105 is arranged in a predetermined number of columns and rows. The pixel cells of each row are selectively readout in response to row select lines. Similarly, pixel cells of each column are selectively readout in response to column select lines. The row select lines in the array 1105 are selectively activated by a row driver 1110 in response to a row address decoder 1120 and the column select lines are selectively activated by a column driver 1160 in response to a column address decoder 1170. The array 1105 is operated by the timing and control circuit 1150, which controls the address decoders 1120, 1170 for selecting the appropriate row and column lines for pixel signal readout.

A sample and hold circuit 1161 associated with the column driver 1160 reads a pixel reset signal (Vrst) and a pixel image signal (Vsig) for selected pixels. A differential signal (Vrst-Vsig) is then amplified by a differential amplifier 1162 for each pixel cell and each pixel cell's differential signal is digitized by an analog-to-digital converter 1175 (ADC). The analog-to-digital converter 1175 supplies the digitized pixel signals to an image processor 1180 which performs various processing functions on image data received from array 1105 and forms a digital image for output.

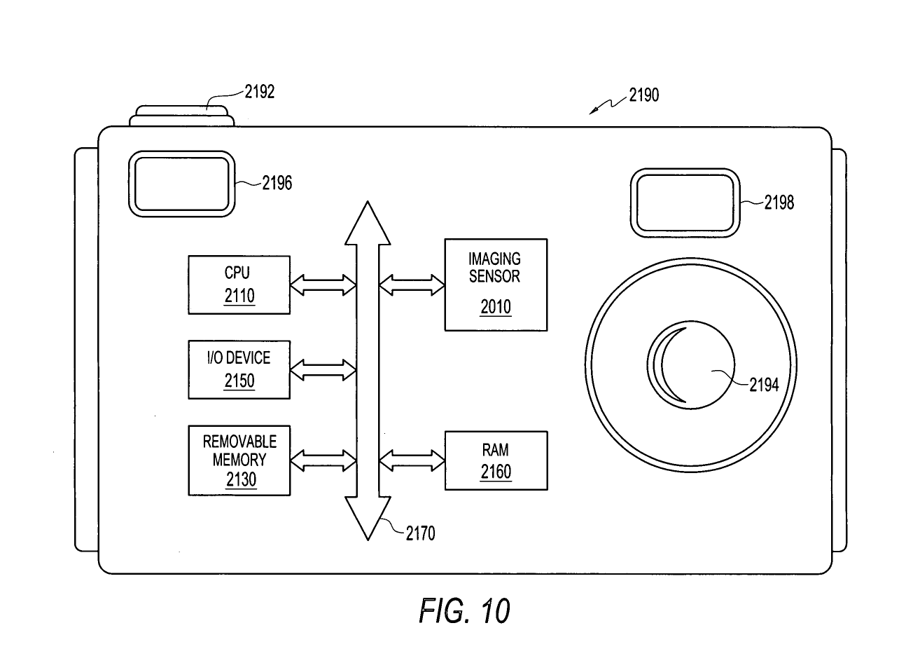

FIG. 10 is a block diagram of a processing system, e.g., a camera system, 2190 incorporating an image sensor 2010 in accordance with the method and apparatus embodiments described herein. A camera system 2190 generally comprises a shutter release button 2192, a view finder 2196, a flash 2198 and a lens system 2194. A camera system 2190 generally also comprises a camera control central processing unit (CPU) 2110, for example, a microprocessor, that controls camera functions and communicates with one or more input/output (I/O) devices 2150 over a bus 2170. The CPU 2110 also exchanges data with random access memory (RAM) 2160 over bus 2170, typically through a memory controller. The camera system may also include peripheral devices such as a removable flash memory 2130 which also communicates with CPU 2110 over the bus 2170. The processing system illustrated in FIG. 10 need not be limited to a camera, but could include any system which receives and operates with image data provided by the image sensor 2010.

The above description and drawings are only to be considered illustrative of specific embodiments, which achieve the features and advantages described herein. Modification and substitutions to specific process conditions and structures can be made. Accordingly, the embodiments of the invention are not to be considered as being limited by the foregoing description and drawings, but is only limited by the scope of the appended claims.

What is claimed as new and desired to be protected by Letters Patent of the United States is:

1. A pixel cell comprising:
a photo-conversion device formed in association with a substrate;
an interlayer dielectric region over said photo-conversion device; and
a photon guiding structure formed over said photo-conversion device and within said interlayer dielectric region, said structure comprising:
a trench formed within at least a portion of said interlayer dielectric region;
a material formed along a sidewall of said trench for internally reflecting photons down said photon guiding structure;
a dielectric formed over said material; and
an optically transparent material formed over said dielectric and filling a remaining portion of said trench.

2. The pixel cell of claim 1, wherein said trench is substantially vertically aligned with said photo-conversion device.

3. The pixel cell of claim 2, wherein cross-sectional shapes of said trench and said photo-conversion device are approximately the same.

4. The pixel cell of claim 2, wherein said trench has a circular cross-sectional shape.

5. The pixel cell of claim 1, wherein said material comprises at least one of aluminum, copper, silver, tungsten, titanium, gold, silicon nitride, titanium oxide or titanium nitride.

6. The pixel cell of claim 1, wherein a thickness of said material is between approximately 50 Å and approximately 1000 Å.

7. The pixel cell of claim 1, wherein said dielectric comprises at least one of TEOS, un-doped silicate glass or silicon nitride.

8. The pixel cell of claim 1, wherein a thickness of said dielectric is between approximately 50 Å and approximately 1000 Å.

9. The pixel cell of claim 1, wherein said optically transparent material comprises at least one of undoped silicate glass, spin-on dielectric, optically-transparent flowable oxide or photoresist.

10. The pixel cell of claim 1, wherein said interlayer dielectric region comprises one or more of interlayer dielectric layers, passivation layers, and metallization layers.

11. An image sensor comprising:
an array of pixel cells, each said pixel cell comprising:
a photodiode formed in association with a substrate;
a trench formed in an interlayer dielectric region, said trench being over said photodiode and substantially vertically aligned with said photodiode;
a material formed along a sidewall of said trench for internally reflecting photons down said trench;
a dielectric formed over said material; and
an optically transparent material filling a remaining portion of said trench; and
a readout circuit for reading signals from said array of pixel cells.

12. The image sensor of claim 11, wherein said material comprises at least one of aluminum, copper, silver, tungsten, titanium, gold, silicon nitride, titanium oxide or titanium nitride.

13. The image sensor of claim 11, wherein said dielectric comprises at least one of TEOS, un-doped silicate glass or silicon nitride.

14. The image sensor of claim 11, wherein said optically transparent material comprises at least one of undoped silicate glass, spin-on dielectric, optically-transparent flowable oxide or photoresist.

15. The image sensor of claim 11, wherein a thickness of said dielectric is between approximately 50 Å and approximately 1000 Å.

16. A system comprising:
a processor; and
an image sensor coupled to said processor, said image sensor comprising an array of pixel cells, each said pixel cell comprising:
a photo-conversion device formed on a substrate,
a trench formed over said photo-conversion device, wherein horizontal cross-sectional shapes of said trench and said photo-conversion device are approximately the same,
a material formed along a sidewall of said trench,
a dielectric formed over said material, and
an optically transparent material filling a remaining portion of said trench.

17. The system of claim 16, wherein said trench is substantially vertically aligned with said photo-conversion device.

18. The system of claim 16, wherein said material comprises at least one of aluminum, copper, silver, tungsten, titanium, gold, silicon nitride, titanium oxide or titanium nitride.

19. The system of claim 16, wherein said dielectric comprises at least one of TEOS, un-doped silicate glass or silicon nitride.

20. The system of claim 16, wherein said optically transparent material comprises at least one of undoped silicate glass, spin-on dielectric, optically-transparent flowable oxide or photoresist.

21. A method of forming a pixel cell, said method comprising:
forming a photo-conversion device on a substrate;
forming an interlayer dielectric region over said photo-conversion device; and
forming a structure over said photo-conversion device and within said interlayer dielectric region, the act of forming said structure comprising:
forming a trench within at least a portion of said interlayer dielectric region,
forming a material along a sidewall of said trench,
forming a dielectric over said material, and
forming an optically transparent material over said dielectric to fill a remaining portion of said trench.

22. The method of claim 21, wherein said trench is substantially vertically aligned with said photo-conversion device.

23. The method of claim 22, wherein horizontal cross-sectional shapes of said trench and said photo-conversion device are approximately the same.

24. The method of claim 22, wherein said trench has a circular horizontal cross-sectional shape.

25. The method of claim 21, wherein a thickness of said material is between approximately 50 Å and approximately 1000 Å.

26. The method of claim 21, wherein a thickness of said dielectric is between approximately 50 Å and approximately 1000 Å.

27. The method of claim 21, wherein said material comprises at least one of aluminum, copper, silver, tungsten, titanium, gold, silicon nitride, titanium oxide or titanium nitride.

28. The method of claim 21, wherein said dielectric comprises at least one of TEOS, un-doped silicate glass or silicon nitride.

29. The method of claim 21, wherein said optically transparent material comprises at least one of undoped silicate glass, spin-on dielectric, optically-transparent flowable oxide or photoresist.

30. The method of claim 21 further comprising forming a color filter array over said interlayer dielectric region.

31. The method of claim 30, wherein said trench extends from a level below said color filter array to a level above said photo-conversion device.

32. A method of forming a photon guiding structure within a pixel cell of an image sensor, comprising:
forming an interlayer dielectric region over a photo-conversion device;
etching a trench into a portion of said interlayer dielectric region, said trench being substantially vertically aligned with said photo-conversion device;
forming a material along a sidewall of said trench;
forming a dielectric over said material; and
forming an optically transparent material over said dielectric to fill a remaining portion of said trench.

33. The method of claim 32, wherein horizontal cross-sectional shapes of said trench and said photo-conversion device are approximately the same.

34. The method of claim 32, further comprising planarizing a top portion of said structure to expose a top surface of said interlayer dielectric region.

35. The method of claim 32, further comprising forming a protective layer over said structure.

36. The method of claim 32, further comprising forming a color filter array over said structure.
